(19) United States
(12) Patent Application Publication
(10) Pub. No.: US 2020/0135685 A1
(43) Pub. Date: Apr. 30, 2020

(54) METHOD FOR DETERMINING BONDING PAD SPACING ON THE SURFACE OF BONDING WIRE CHIP

(71) Applicant: Lansus Technologies Inc., Shenzhen, Guangdong (CN)

(72) Inventors: Xianwei WU, Shenzhen, Guangdong (CN); Hua LONG, Shenzhen, Guangdong (CN); Rui ZHENG, Shenzhen, Guangdong (CN)

(21) Appl. No.: 16/619,578

(22) PCT Filed: Sep. 30, 2017
(86) PCT No.: PCT/CN2017/104711

§ 371 Date: Dec. 5, 2019

(30) Foreign Application Priority Data
Jun. 6, 2017 (CN) 201710419620.2

(51) Int. Cl. H01L 23/00

(52) U.S. Cl. CPC H01L 24/43; H01L 2224/45015; H01L 24/85; H01L 24/03

(57) ABSTRACT

A method for determining a bonding pad spacing on the surface of a bonding wire chip includes the steps of setting a loop height (“K”); selecting a capillary, measuring an expansion angle of a capillary sharp mouth (“C”); measuring the diameter of the capillary sharp mouth (“T”); measuring the hole diameter of the capillary (“H”); and determining a bonding pad spacing on the surface of a bonding wire chip (“P”). The formula is as follows: P=(T+H)/2+[tan(C/2)]*K. This method more accurately determines bonding pad spacing on the surface of a bonding wire chip, thereby providing a wider performance adjustment space. Additionally, problems, such as mutual inductance abnormalities caused by wire deformation or even by short circuits with other circuits due to the contact between a packaged capillary and a bonded wire can be lowered, thereby improving the working efficiency and reducing the number of times verification is performed.

### TECHNICAL FIELD

The invention relates to the field of bonding, and in particular, to a method for determining a bonding pad spacing on the surface of a bonding wire chip.

### BACKGROUND

Compared with other IC functional products, PA (PA refers to power amplifier) products mainly focus on RF (RF refers to radio frequency) output/input stability, and chips are early developed materials and have determined input and output performance in general, with litter room to adjust. Thus, a wide adjustment space for the loop height and the stability of a 3D outline are required during bonding wire processing for packaging.

In case where the loop height is large and the bonding pad spacing is small, a formed 3D outline may be touched during packaging operation, that is to say, during packaging operations, the stability of the 3D outline will be destroyed due to failing to take the bonding pad spacing into consideration in advance. Besides, to obtain a larger adjustment space for packaging, the bonding pad spacing should be as large as possible when the sizes and positions of bonding pads of a chip are designed. However, due to the small size of the chip, the adjustability room of the bonding pad spacing is little, and it is necessary to acquire the relationship between the loop height and the bonding pad spacing in advance, so as to complete packaging more smoothly.

### SUMMARY

To solve the above problems, The invention provides a method for determining a bonding pad spacing on the surface of a bonding wire chip.

The method for determining a bonding pad spacing on the surface of a bonding wire chip comprises the following steps:

setting a loop height, and defining the loop height as K:

selecting a capillary, measuring an expansion angle of a capillary sharp mouth, and defining expansion angle as C;

measuring the diameter of the capillary sharp mouth, and defining diameter as T;

measuring a hole diameter of the capillary, and defining the hole diameter as H; and

determining a bonding pad spacing on the surface of a bonding wire chip, and defining the spacing as P, where a formula is as follows:

P=(T+H)/2+[tan(C/2)]*K.

Particularly, the method further comprises the following steps:

carrying out rounding processing on the bonding pad spacing obtained by the formula.

Preferably, when a wire diameter is 25 μm, the expansion angle C of the capillary sharp mouth of the selected capillary is 30°.

Preferably, when the wire diameter is 25 μm, the diameter T of the capillary sharp mouth of the selected capillary is 80 μm-100 μm.

Particularly, the hole diameter H of the capillary is set to be greater than the wire diameter.

More particularly, the hole diameter H of the capillary is set to be greater than the wire diameter by 3 μm-8 μm.

By means of the method of the invention, the bonding pad spacing on the surface of the bonding wire chip can be more accurately determined, thereby being able to provide a wider performance adjustment space; and in addition, the problems, such as mutual inductance abnormalities, caused by wire deformation or even by short circuits with other circuits due to the contact between a packaged capillary and a bonding wire can also be lowered, thereby improving the working efficiency and reducing the number of times that verification is performed.

### BRIEF DESCRIPTION OF THE DRAWINGS

FIG. 1 is a schematic diagram of a method for determining a bonding pad spacing on the surface of a bonding wire chip of the invention.

### DETAILED DESCRIPTION OF EMBODIMENTS

For the sake of a better understanding of the technical solution and advantages of the invention, the specific implementations of the invention are further explained below in combination with the accompanying drawings and the embodiments. However, the following implementations and embodiments are only illustrative, and not intended to limit the invention.

To obtain a larger adjustment space for packaging, a bonding pad spacing should be as large as possible when the sizes and positions of bonding pads of a chip are designed. However, due to the small size of the chip, the adjustability room of the bonding pad spacing islitter, and it is necessary to acquire the relation between a loop height and the bonding pad spacing in advance, so as to complete packaging more smoothly. In the packaging process, the most common tool is a capillary which is a consumable part used for guiding a bonding wire, transmitting the parameters of bonding wire devices, and assisting in bonding a bonded ball with a bonding pad.

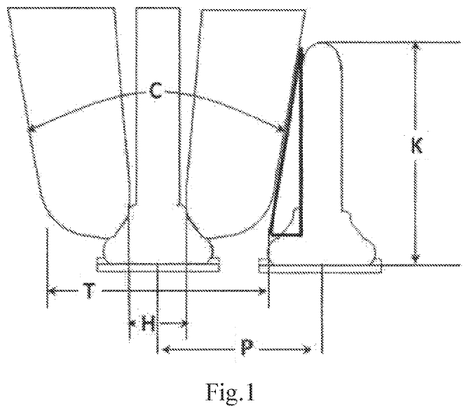

FIG. 1 illustrates a method for determining a bonding pad spacing on the surface of a bonding wire chip. The method comprises the following steps:

Step 1: a loop height is set and is defined as K. A loop refers to a bonding wire shape formed by releasing the bonding wire in the motion track of a capillary. The loop height is manually set as actually needed in operation and is the basis of subsequent operations, and if the loop height is increased and the bonding wire shape needs to remain unchanged, a bonding pad spacing on the surface of a bonding wire chip needs to be changed accordingly.

Step 2: a capillary is selected: (1) an expansion angle of a capillary sharp mouth is measured and is defined as C: (2) the diameter of the capillary sharp mouth is measured and is defined as T: and (3) a hole diameter of the capillary is measured and is defined as H. Wherein, as shown in FIG. 1, the expansion angle of the capillary sharp mouth refers to an angle between an outline of the sharp mouth and a longitudinal axis, the diameter of the capillary sharp mouth refers to the diameter of a planar circle of the sharp mouth, and the hole diameter of the capillary refers to the smallest diameter of an internal hole of a guide wire in the capillary. The diameter of a bonding wire is abbreviated as a wire diameter. Preferably, when the wire diameter is selected as 25 μm, the parameters of the selected capillary are as follows: the expansion angle C of the capillary sharp mouth is 30°, and the diameter T of the capillary sharp mouth of the selected capillary is 80 μm-100 μm. The selected capillary should not be too large and should be easy to control, so as to perform construction on the surface of the bonding wire chip more easily and complete packaging finally. Besides, the hole diameter H of the capillary should be set greater than the wire diameter. Specifically, the hole diameter H of the capillary is set to be greater than the wire diameter by 3 μm-8 μm. The bonding wire swings in a hole of the capillary, so after the bonding wire and the bonding pads are processed stably, to make the wire form a loop according to the capillary track, a gap needs to be reserved namely the wire diameter is 25 μm generally, and correspondingly the hole diameter of the capillary is 28 μm-33 μm.

Step 3: the bonding pad spacing on the surface of the bonding wire chip is determined and is defined as P, where the formula is as follows:

P=(T+H)/2+[tan(C/2)]*K.

Particularly, the method further comprises the following step: rounding processing is carried out on the bonding pad spacing obtained through the formula.

Specifically, in order to avoid the touch of a formed 3D outline during packaging and to make the operations simple, it is necessary to carry out rounding processing on P calculated according to the formula to obtain the minimum value Pmin of P. For instance, P is approximate to Pmin=101 μm in the case of P=100.1 μm. That is, the bonding pad spacing on the surface of the bonding wire chip should be at least 101 μm, so that the formed 3D outline will not be touched. In this way, the problems, such as mutual inductance abnormalities, caused by wire deformation or even by short circuits with other circuits due to the contact between a packaged capillary and a bonded wire are lowered, thereby improving the working efficiency and reducing the number of times that verification is performed.

### Embodiment 1

In the case where the wire diameter is 25 μm, a loop height K is set as 280 μm.

A capillary is selected, an expansion angle C of a capillary sharp mouth is 30°, the diameter T of the capillary sharp mouth is 80 μm, and a hole diameter H of the capillary is selected as 30 μm.

A bonding pad spacing on the surface of a bonding wire chip is determined and is defined as P, where the formula is as follows:

P=(T+H)/2+[tan(C/2)]*K.

Plugging numerical values into the above formula:

P=(T+H)/2+[tan(C/2)]*K.

P=½(80 μm+30 μm)+(tan 15°)*280 μm

=55 μm+75.04 μm

=130.04 μm

Rounding processing is carried out on P, that is to say, and the P value is rounded off to meet Pmin=131 μm. As such, the bonding pad spacing on the surface of the bonding wire chip is determined to be at least 131 μm. In this premise, the formed 3D outline will not be touched when other operations are performed, so that the problems, such as mutual inductance abnormalities, caused by wire deformation or even by short circuits with other circuits due to the contact between a packaged capillary and a bonded wire are lowered, thereby improving the working efficiency and reducing the number of times that verification is performed.

It should be noted that the embodiments mentioned above in combination with the accompanying drawings are only illustrative, and are not used for limiting the protection scope of the invention. Those ordinarily skilled in the art would appreciate that all modifications or equivalent replacements made without deviating from the spirit and scope of the invention should also fall within the scope of invention. Besides, unless otherwise specified in the context, words in a singular form include plural forms, and vice-versa. In addition, unless otherwise explicitly specified, part or all of any embodiments can be implemented in combination with part or all of other embodiments.

What is claimed is:

1. A method for determining a bonding pad spacing on a surface of a bonding wire chip, comprising:
setting a loop height, and defining the loop height as K;
selecting a capillary, measuring an expansion angle of a capillary sharp mouth, and defining the expansion angle as C;
measuring a diameter of the capillary sharp mouth, and defining the diameter as T;
measuring a hole diameter of the capillary, and defining the hole diameter as H; and
determining a bonding pad spacing on a surface of a bonding wire chip, and defining the spacing as P according to a formula as follow:
P=(T+H)/2+[tan(C/2)]*K.

2. The method according to claim 1, further comprising:
carrying out rounding processing on the bonding pad spacing obtained with the formula.

3. The method according to claim 1, wherein the expansion angle C of the capillary sharp mouth of the selected capillary is 30° when a wire diameter is 25 μm.

4. The method according to claim 1, wherein the diameter T of the capillary sharp mouth of the selected capillary is 80 μm-100 μm when a wire diameter is 25 μm.

5. The method according to claim 1, wherein the hole diameter H of the capillary is set to be greater than a wire diameter.

6. The method according to claim 5, wherein the hole diameter H of the capillary is set to be greater than the wire diameter by 3 μm-8 μm.
